(19) United States
(12) Patent Application Publication
(10) Pub. No.: US 2024/0096814 A1
(43) Pub. Date: Mar. 21, 2024

(54) SEMICONDUCTOR PROCESSING FOR ALIGNMENT MARK

(71) Applicant: TEXAS INSTRUMENTS INCORPORATED, Dallas, TX (US)

(72) Inventors: Guoyong Zhang, Chengdu (CN); She Yu Tang, Chengdu (CN); Shu Min Ma, Chengdu (CN); Lei Zhang, Chengdu (CN); Peng Hu, Chengdu (CN); Fei Yu, Chengdu (CN)

(21) Appl. No.: 17/948,343

(22) Filed: Sep. 20, 2022

(51) Int. Cl. H01L 23/544

(52) U.S. Cl. CPC H01L 23/544; H01L 2223/54426

(57) ABSTRACT

The present disclosure generally relates to semiconductor processing in which an alignment mark is formed. An example is method of semiconductor processing. First and second recesses are formed in a semiconductor substrate. A conformal dielectric layer is formed in the first and second recesses and over the semiconductor substrate. A fill material is formed over the conformal dielectric layer in the first recess and over the conformal dielectric layer in the second recess. The fill material fills at least the first recess over the conformal dielectric layer. The fill material in the first and second recesses is recessed to below a top surface of the conformal dielectric layer. The recessed fill material in the first and second recesses is etched. Exposed portions of the conformal dielectric layer are etched. The second recess including the conformal dielectric layer and the recessed fill material disposed therein forms an alignment mark.

### BACKGROUND

Photolithography is a common technique used in semiconductor processing. In semiconductor processing, a photolithography process may use an alignment mark disposed on a substrate being processed. A photomask used for patterning in the photolithography process may be aligned relative the substrate by using the alignment mark. Generally, an alignment mark may be a unique structure on the substrate and thus may be identified, such as by an automatic detection system, for alignment of the photomask.

### SUMMARY

An example described herein is a method of semiconductor processing. A first recess and a second recess are formed in a semiconductor substrate. A conformal dielectric layer is formed in the first recess and the second recess and over the semiconductor substrate. A fill material is formed over the conformal dielectric layer in the first recess and over the conformal dielectric layer in the second recess. The fill material fills at least the first recess over the conformal dielectric layer. The fill material in the first recess and the fill material in the second recess are recessed to below a top surface of the conformal dielectric layer. The recessed fill material in the first recess and the recessed fill material in the second recess are etched. Exposed portions of the conformal dielectric layer are etched. The second recess including the conformal dielectric layer and the recessed fill material disposed therein forms an alignment mark.

Another example described herein is a method of semiconductor processing. A first trench and a second trench are formed in a semiconductor substrate. The first trench is in a die area on the semiconductor substrate. The second trench is in a scribe line area on the semiconductor substrate. A conformal dielectric layer is formed in the first trench and the second trench and over the semiconductor substrate. A semiconductor material is formed over the conformal dielectric layer in the first trench and over the conformal dielectric layer in the second trench. The semiconductor material in the first trench and the semiconductor material in the second trench are recessed to below a top surface of the conformal dielectric layer. The recessed semiconductor material in the first trench and the recessed semiconductor material in the second trench are etched. Exposed portions of the conformal dielectric layer are etched.

A further example described herein is a method of semiconductor processing. An isolation trench and an alignment mark trench are formed in a semiconductor substrate. The isolation trench is in a die area on the semiconductor substrate. A first conformal dielectric layer is formed in the isolation trench and the alignment mark trench and over the semiconductor substrate. A first fill material is formed over the first conformal dielectric layer in the isolation trench and over the first conformal dielectric layer in the alignment mark trench. The first fill material in the isolation trench and the first fill material in the alignment mark trench are recessed to below a top surface of the first conformal dielectric layer. The recessed first fill material in the isolation trench and the recessed first fill material in the alignment mark trench are etched. Exposed portions of the first conformal dielectric layer are etched. A second conformal dielectric layer is formed over the recessed first fill material and the first conformal dielectric layer in the isolation trench and over the recessed first fill material and the first conformal dielectric layer in the alignment mark trench. A second fill material is formed over the second conformal dielectric layer in the isolation trench and over the second conformal dielectric layer in the alignment mark trench. The second fill material fills the isolation trench over the second conformal dielectric layer. The second fill material fills the alignment mark trench over the second conformal dielectric layer. The first conformal dielectric layer, the recessed first fill material, the second conformal dielectric layer, and the second fill material in the isolation trench form a trench isolation structure in the die area. A photomask is aligned relative to the semiconductor substrate using the alignment mark trench as an alignment mark. The alignment mark trench includes the first conformal dielectric layer, the recessed first fill material, the second conformal dielectric layer, and the second fill material disposed therein.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a layout view of a substrate according to some examples.

FIG. 2 is a flowchart of a method of semiconductor processing according to some examples.

FIGS. 3 through 16 are cross-sectional views of a substrate at different stages of a first example method of semiconductor processing according to some examples.

FIGS. 17 through 30 are cross-sectional views of a substrate at different stages of a second example method of semiconductor processing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to semiconductor processing in which an alignment mark is formed. In examples described herein, an alignment mark can undergo the same processing as another structure on a semiconductor substrate. In some examples, the other structure is or includes an isolation structure, such as a deep trench isolation (DTI) structure, in the semiconductor substrate. Hence, formation of the alignment mark may be easily integrated in the processing of the semiconductor substrate. Additionally, using processing described herein, formation of a residual material during formation of the alignment mark may be reduced or avoided, and defects resulting from the residual material may therefore be reduced or avoided. Other benefits or advantages may be achieved by various examples.

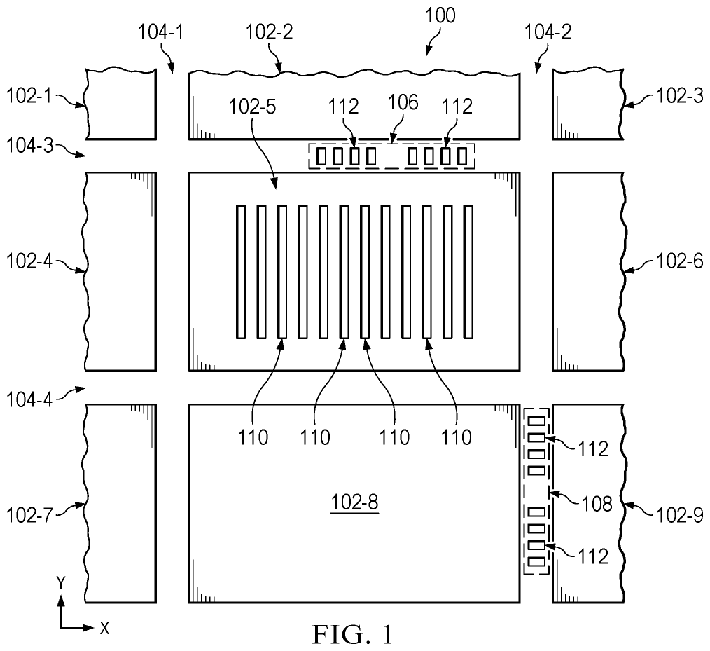

FIG. 1 is a layout view of a substrate 100 according to some examples. FIG. 1 shows an X-Y coordinate axes for ease of reference in the layout view. The substrate 100 can be or include a wafer, in some examples. The substrate 100 includes integrated circuit (IC) die areas 102-1, 102-2, . . . 102-9 and scribe line areas 104-1, 104-2, 104-3, 104-4. The IC die areas 102-1 to 102-9 are arranged in an array. The scribe line areas 104-1, 104-2 extend longitudinally in respective y-directions, and the scribe line areas 104-3, 104-4 extend longitudinally in respective x-directions. A respective scribe line area 104-1 to 104-4 is disposed laterally between neighboring IC die areas 102-1 to 102-9, and various portions of scribe line areas 104-1 to 104-4 laterally and continuously encircle each IC die areas 102-1 to 102-9. For example, the scribe line area 104-3 is disposed laterally between neighboring IC die areas 102-2, 102-5, and portions of the scribe line areas 104-1 to 104-4 laterally and continuously encircle the IC die area 102-5.

The substrate 100 includes a first alignment mark area 106 and a second alignment mark area 108. The first alignment mark area 106 is disposed in the scribe line area 104-3, and the first alignment mark area 106 extends longitudinally in an x-direction. The second alignment mark area 108 is disposed in the scribe line area 104-2, and the second alignment mark area 108 extends longitudinally in a y-direction.

First recesses 110 are disposed in the substrate 100 in the IC die area 102-5 as an example. Recesses may also be in other IC die areas 102-1 to 102-9, although not illustrated so as to not obscure various aspects described herein. The first recesses 110 may be implemented to form respective isolation structures, such as DTI structures, in an IC in the IC die area 102-5 and may, at least in part, define respective active areas in the IC die area 102-5 in or on which one or more devices (e.g., a transistor) may be formed. The first recesses 110 extend with longitudinal lengths in respective y-directions, and each first recess 110 has a width in an x-direction (e.g., perpendicular to the respective longitudinal length). The first recesses 110, as described subsequently, may be etched into a semiconductor substrate of the substrate 100 and may be filled to varying levels and with varying materials during different stages of processing. The first recesses 110, as illustrated, are trenches; although in other examples, the first recesses 110 may take other forms.

Second recesses 112 are also disposed in the substrate 100 in each of the first alignment mark area 106 and the second alignment mark area 108. The second recesses 112 in the first alignment mark area 106 extend with longitudinal lengths in respective y-directions, and each second recess 112 in the first alignment mark area 106 has a width in an x-direction (e.g., perpendicular to the respective longitudinal length). The second recesses 112 in the second alignment mark area 108 extend with longitudinal lengths in respective x-directions, and each second recess 112 in the second alignment mark area 108 has a width in a y-direction (e.g., perpendicular to the respective longitudinal length). The second recesses 112 in the first alignment mark area 106 are implemented to form a first alignment mark, and the second recesses 112 in the second alignment mark area 108 are implemented to form a second alignment mark. The second recesses 112, like the first recesses 110, may be etched into a semiconductor substrate of the substrate 100 and may be filled to varying levels and with varying materials during different stages of processing. The second recesses 112, as illustrated, are trenches; although in other examples, the first recesses 110 may take other forms.

The first and second alignment marks on a substrate are used during processing to align a photomask. Photolithography can be implemented in processing to form a patterned photoresist that is used as a mask. The patterned photoresist can mask portions of layers or structures for transferring the pattern of the patterned photoresist into those layers or structures by etching, as an example. A patterned photoresist may also mask portions of layers or structures in which dopants are generally not to be implanted during a dopant implantation process. During semiconductor processing, features formed using respective patterned photoresists may be aligned by aligning the photomasks relative to the substrate to thereby align the patterned photoresists. The first and second alignment marks may be used to align some photomasks for such photolithography processes. The first alignment mark (e.g., the second recesses 112 in the first alignment mark area 106) may be used to align a photomask relative to the substrate 100 in an x-direction, and the second alignment mark (e.g., the second recesses 112 in the second alignment mark area 108) may be used to align a photomask relative to the substrate 100 in a y-direction. In such manner, photomasks may be aligned with a same location on the substrate 100, within some manufacturing tolerance, generally.

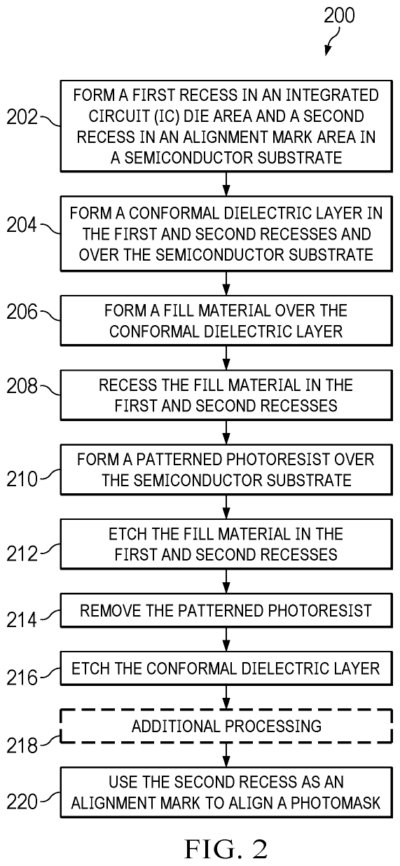

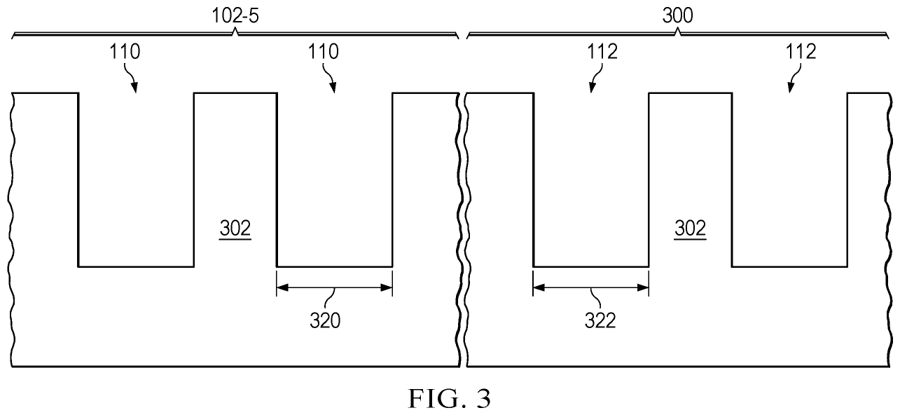

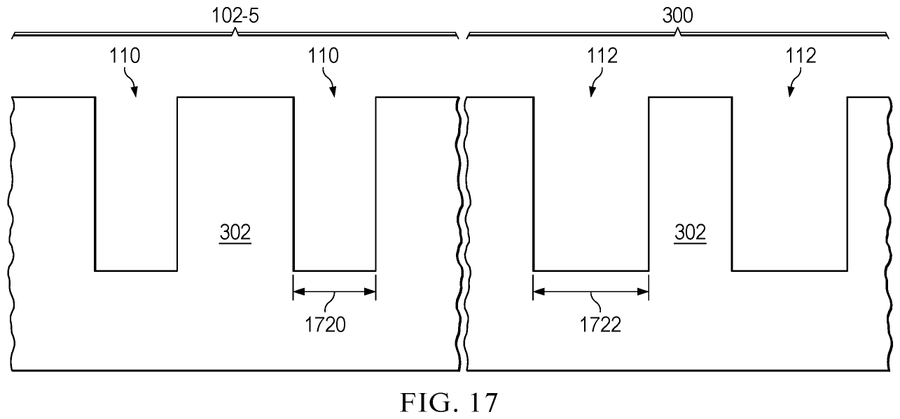

FIG. 2 is a flowchart of a method 200 of semiconductor processing according to some examples. The method 200 of FIG. 2 is described in the context of a first example in FIGS. 3 through 16, which are cross-sectional views of the substrate 100 at different stages of semiconductor processing according to some examples. The method 200 of FIG. 2 is also described in the context of a second example in FIGS. 17 through 30, which are cross-sectional views of the substrate 100 at different stages of semiconductor processing according to some examples. The cross-sectional views of FIGS. 3 through 30 show a partial cross-section of the IC die area 102-5 along an x-direction, and show a partial cross-section of the first alignment mark area 106 along an x-direction and/or of the second alignment mark area 108 along a y-direction. A generic alignment mark area 300 is used herein to generically refer to the first alignment mark area 106, the second alignment mark area 108, or both.

In the context of the first example of FIGS. 3 through 16, referring to block 202 of FIG. 2, a first recess in an IC die area and a second recess in an alignment mark area are formed in a semiconductor substrate. In FIG. 3, first recesses 110 are formed in an IC die area 102-5 in a semiconductor substrate 302, and second recesses 112 are formed in an alignment mark area 300 in the semiconductor substrate 302. The first recesses 110 in the IC die area 102-5 each have a width 320, and the second recesses 112 in the alignment mark area 300 each have a width 322. The width 320 of the first recesses 110 in the IC die area 102-5 is equal to the width 322 of the second recesses 112 in the alignment mark area 300.

The semiconductor substrate 302, in some examples, can include a support substrate and one or more epitaxial layers epitaxially grown on the support substrate. The support substrate can be a bulk semiconductor substrate, a semiconductor-on-insulator (SOI) substrate, or any other appropriate substrate. In some examples, the semiconductor substrate 302 can be a bulk semiconductor substrate, a SO) substrate, or any other appropriate substrate. For example, the semiconductor substrate 302 can be or include a bulk silicon wafer, which may or may not have one or more epitaxial layers of a semiconductor material epitaxially grown thereover.

The first recesses 110 and second recesses 112 can be formed using photolithography and etch processes. A photolithography process can include depositing, such as by spin-on, a photoresist on a substrate (e.g., the semiconductor substrate 302), exposing the photoresist to a pattern of light using a photomask, and developing the photoresist. Developing the photoresist can remove the exposed or unexposed portions of the photoresist depending on whether the photoresist is positive or negative tone, and once developed, a patterned photoresist may remain. An example etch process is a reactive ion etch (RIE), which is generally anisotropic or directional. Other etch processes can be implemented. After the etch process, remaining patterned photoresist can be removed using an ash process.

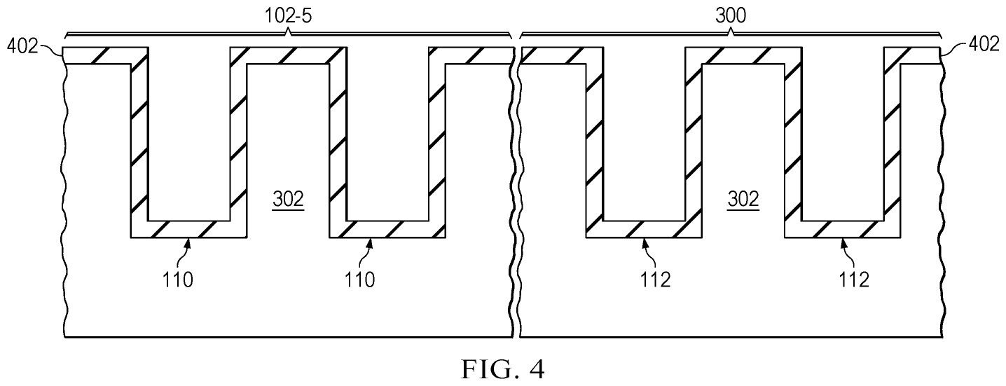

Referring to block 204 of FIG. 2, a conformal dielectric layer is formed in the first recess and the second recess and over the semiconductor substrate. In FIG. 4, a first conformal dielectric layer 402 is formed in the first recesses 110 in the IC die area 102-5 and the second recesses 112 in the alignment mark area 300 and over the semiconductor substrate 302. The first conformal dielectric layer 402 is formed over (e.g., possibly, on) a top surface of the semiconductor substrate 302 and along sidewalls and over bottom surfaces that define the first recesses 110 and second recesses 112. In some examples, the first conformal dielectric layer 402 may be or include an oxide, such as tetraethyl orthosilicate (TEOS), or any other dielectric material. The first conformal dielectric layer 402 can be formed using any appropriate deposition process, such as a chemical vapor deposition (CVD) process, like sub-atmospheric CVD (SACVD).

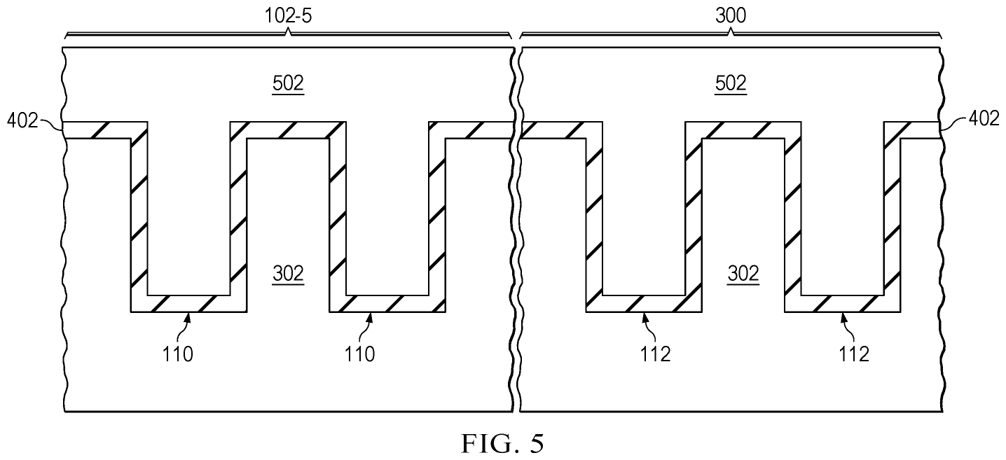

Referring to block 206 of FIG. 2, a fill material is formed over the conformal dielectric layer. In FIG. 5, a first fill material 502 is formed over the first conformal dielectric layer 402. The first fill material 502, as deposited, fills the previously un-filled portions of the first recesses 110 and second recesses 112 over the first conformal dielectric layer 402 and is deposited to a thickness over the top surface of the semiconductor substrate 302. In some examples, the first fill material 502 can be a semiconductor material, such as polysilicon. The first fill material 502 can be deposited by any appropriate deposition process, such as CVD, physical vapor deposition (PVD), the like, or a combination thereof.

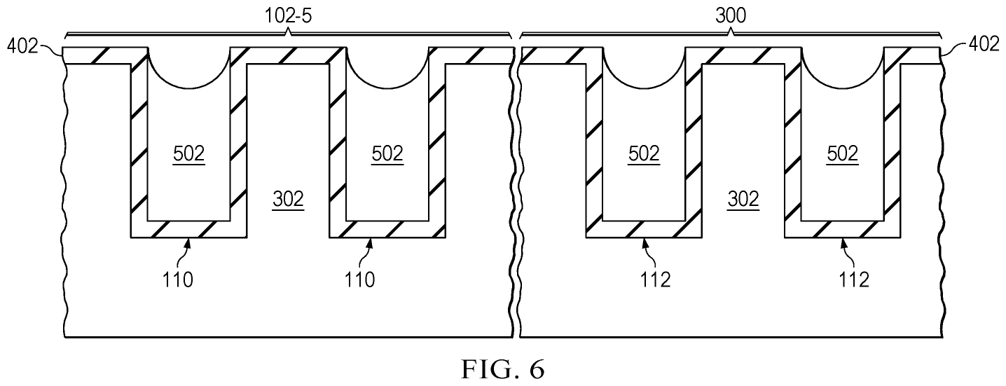

Referring to block 208 of FIG. 2, the fill material is recessed in the first recess and the second recess. In FIG. 6, the first fill material 502 is recessed in the first recesses 110 in the IC die area 102-5 and in the second recesses 112 in the alignment mark area 300. The first fill material 502 in the first recesses 110 and the second recesses 112 is recessed below a top surface of the first conformal dielectric layer 402, which may be over a top surface of the semiconductor substrate 302. The first fill material 502 can be recessed using an appropriate etch process, which may be a wet etch process. In examples in which the first fill material 502 is polysilicon, the first fill material 502 may be recessed using a wet etch including tetramethylammonium hydroxide (TMAH), for example. The first fill material 502 is removed from over the top surface of the first conformal dielectric layer 402, and respective remaining first fill material 502 in the first recesses 110 and second recesses 112 may have a dished upper surface below the top surface of the first conformal dielectric layer 402.

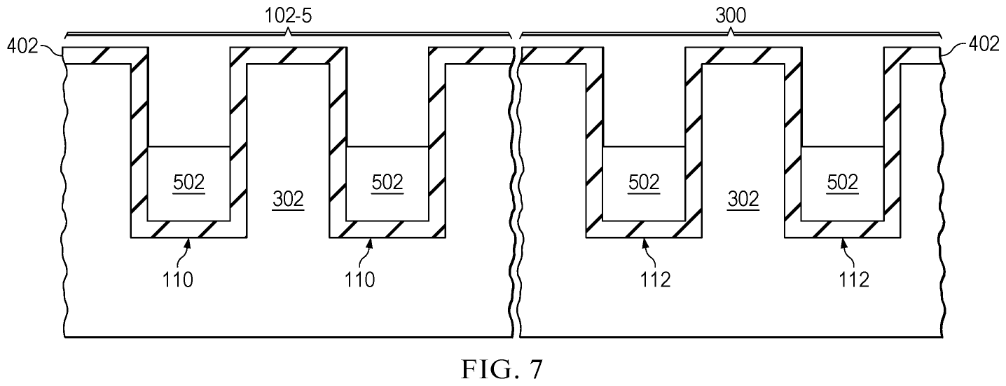

Referring to block 210 of FIG. 2, a patterned photoresist is formed over the semiconductor substrate, and at block 212, the fill material in the first recess and the second recess is etched. In FIG. 7, the first fill material 502 in the first recesses 110 in the IC die area 102-5 is etched, and the first fill material 502 in the second recesses 112 in the alignment mark area 300 is etched. The patterned photoresist (which is formed over the semiconductor substrate 302) of block 210 is not illustrated in FIG. 7 since the patterned photoresist is not disposed in the area of the cross-section of FIG. 7 but is disposed in, for example, another area of the IC die area 102-5. The first recesses 110 and second recesses 112 (with first conformal dielectric layer 402 and first fill material 502 disposed therein) are exposed through the patterned photoresist formed at block 210. No portion of the patterned photoresist is disposed directly over the first recesses 110, and no portion of the patterned photoresist is disposed directly over the second recesses 112. The patterned photoresist can be formed using a photolithography process as described above. The second recesses 112 (with first conformal dielectric layer 402 and first fill material 502 disposed therein) may be used as an alignment mark for aligning a photomask in the photolithography process. With the patterned photoresist over the semiconductor substrate 302, the first fill material 502 in the first recesses 110 and second recesses 112 is etched. The first fill material 502 can be etched using an appropriate etch process, such as RIE.

Referring to block 214 of FIG. 2, the patterned photoresist is removed. After the first fill material 502 in the first recesses 110 and second recesses 112 is etched, the patterned photoresist (formed at block 210) can be removed using an ash process. The semiconductor substrate 302 can thereafter be cleaned using a wet strip or clean process.

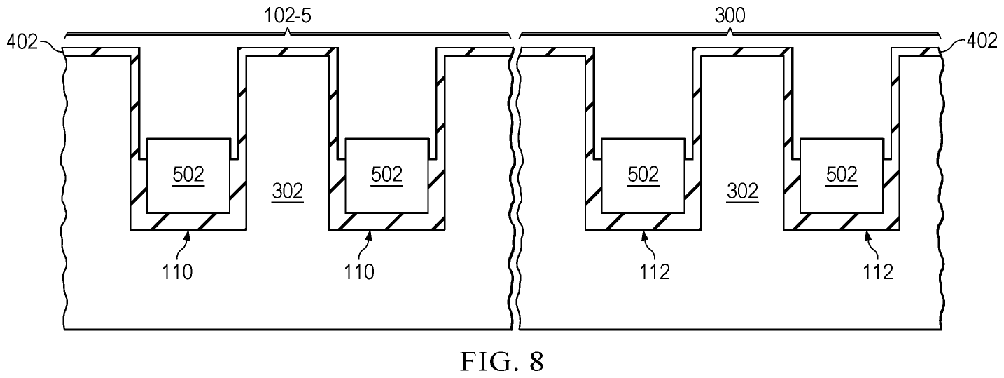

Referring to block 216 of FIG. 2, the conformal dielectric layer is etched. In FIG. 8, the first conformal dielectric layer 402 is etched. The etch can thin exposed portions of the first conformal dielectric layer 402. In the first recesses 110 and second recesses 112, the etch can etch portions of the first conformal dielectric layer 402 along sidewalls of the first recesses 110 and second recesses 112 below top surfaces of the first fill material 502 (e.g., due to the isotropic nature of the etch). The first conformal dielectric layer 402 can be etched using an appropriate etch process, which may be a wet etch process. In examples in which the first conformal dielectric layer 402 is silicon oxide, the first conformal dielectric layer 402 may be etched using a wet etch including diluted hydrofluoric acid (dHF), for example.

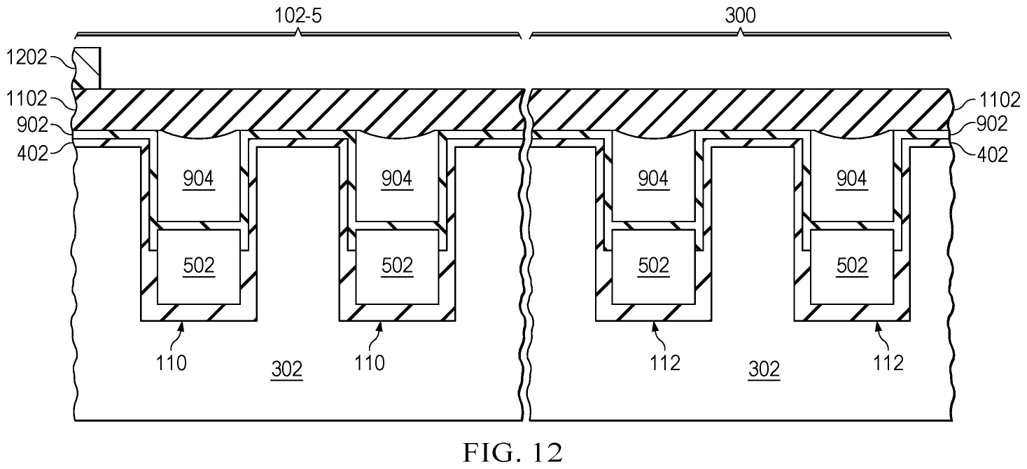

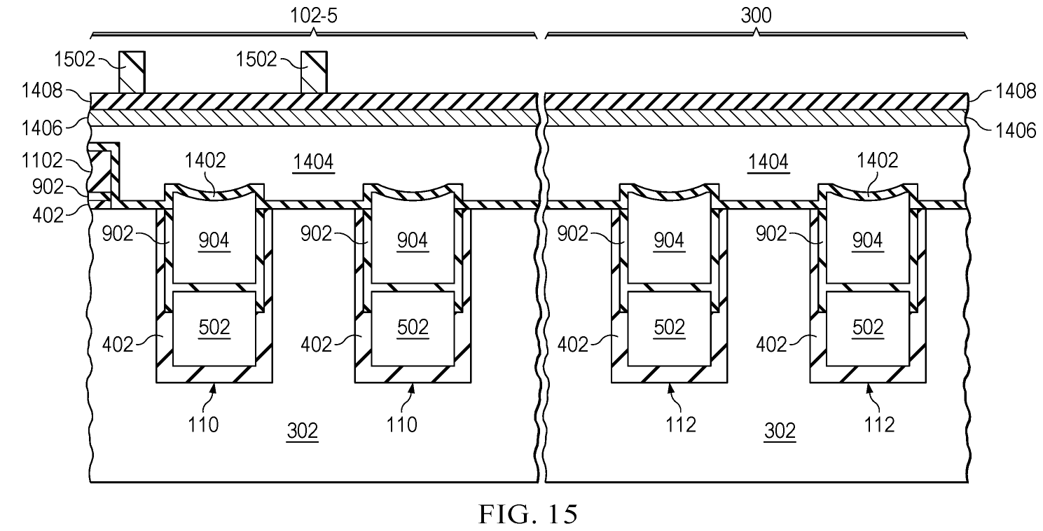

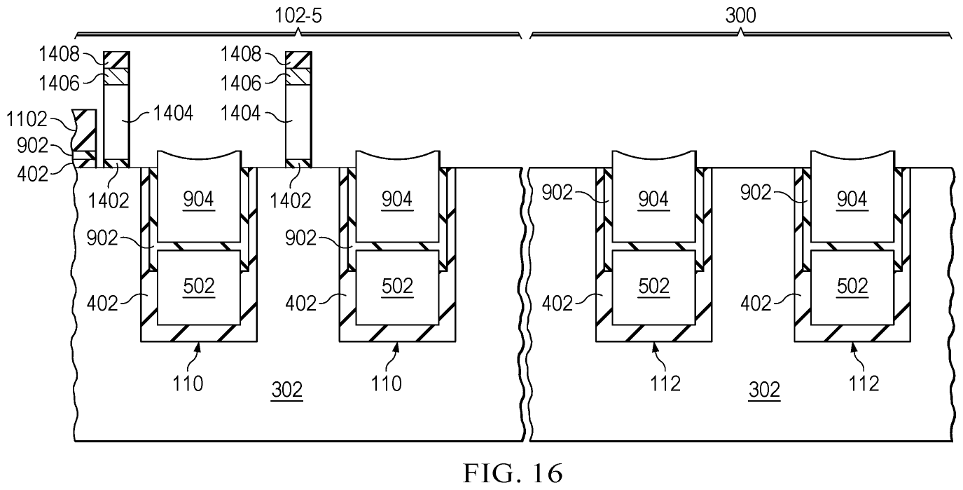

Referring to block 218 of FIG. 2, additional processing is, optionally, performed on the semiconductor substrate, and at block 220, the second recess (and any material disposed therein) is used as an alignment mark to align a photomask. Patterning photoresists in FIGS. 12 and 15 are examples in which the second recesses 112 (and material disposed therein) in the alignment mark area 300 are used as an alignment mark to align a photomask. Other figures through FIG. 16 illustrate various additional processing that may be performed.

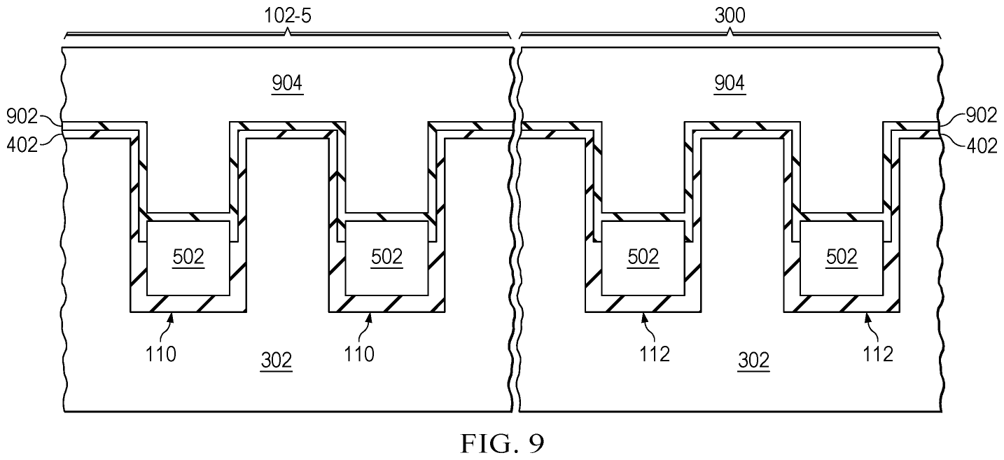

Referring to FIG. 9, a second conformal dielectric layer 902 is formed over the first conformal dielectric layer 402 and first fill material 502, and second fill material 904 is formed over the second conformal dielectric layer 902. The second conformal dielectric layer 902 is formed over or along the first conformal dielectric layer 402 that is in the first recesses 110 in the IC die area 102-5 and in the second recesses 112 in the alignment mark area 300. The second conformal dielectric layer 902 is formed over the first conformal dielectric layer 402 that is over the top surface of the semiconductor substrate 302 and that is along sidewalls that define the first recesses 110 and second recesses 112. The second conformal dielectric layer 902 is also formed over the first fill material in the first recesses 110 and the second recesses 112. In some examples, the second conformal dielectric layer 902 may be or include an oxide, such as TEOS, or any other dielectric material. The second conformal dielectric layer 902 can be formed using any appropriate deposition process, such as a CVD process, like SACVD. The second fill material 904 is formed over the second conformal dielectric layer 902. The second fill material 904, as deposited, fills the previously un-filled portions of the first recesses 110 and second recesses 112 over the second conformal dielectric layer 902 and is deposited to a thickness over the top surface of the semiconductor substrate 302. In some examples, the second fill material 904 can be a semiconductor material, such as polysilicon. The second fill material 904 can be deposited by any appropriate deposition process, such as CVD, PVD, the like, or a combination thereof.

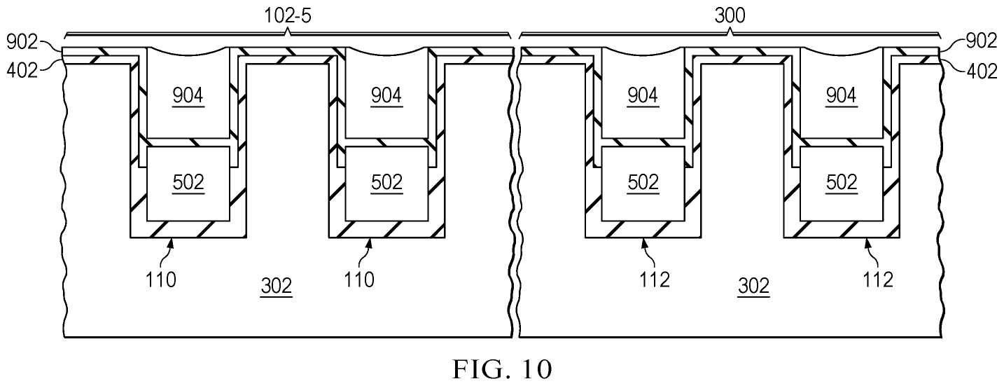

Referring to FIG. 10, the second fill material 904 is recessed in the first recesses 110 in the IC die area 102-5 and in the second recesses 112 in the alignment mark area 300. The second fill material 904 can be recessed using an appropriate etch process, which may be a wet etch process. In examples in which the second fill material 904 is polysilicon, the second fill material 904 may be recessed using a wet etch including TMAH, for example. The second fill material 904 is removed from over a top surface of the second conformal dielectric layer 902, and respective remaining second fill material 904 in the first recesses 110 and second recesses 112 may have a dished upper surface.

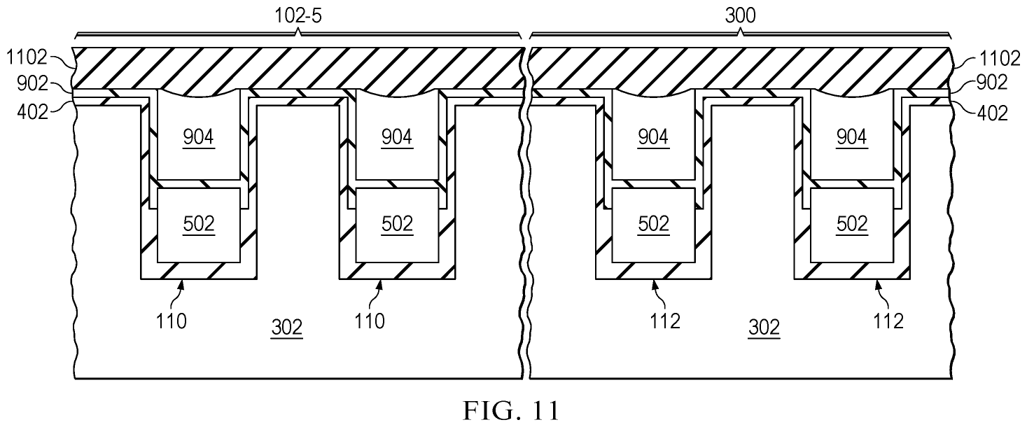

Referring to FIG. 11, a dielectric layer 1102 is deposited over the second conformal dielectric layer 902 and the second fill material 904. In some examples, the dielectric layer 1102 may be or include an oxide or any other dielectric material. The dielectric layer 1102 can be formed using any appropriate deposition process, such as a CVD process.

Referring to FIG. 12, a patterned photoresist 1202 is formed over the dielectric layer 1102 in the IC die area 102-5. The patterned photoresist 1202 can be formed using a photolithography process as described above. The second recesses 112 (with conformal dielectric layers 402, 902 and fill material 502, 904 disposed therein) are used as an alignment mark for aligning a photomask in the photolithography process.

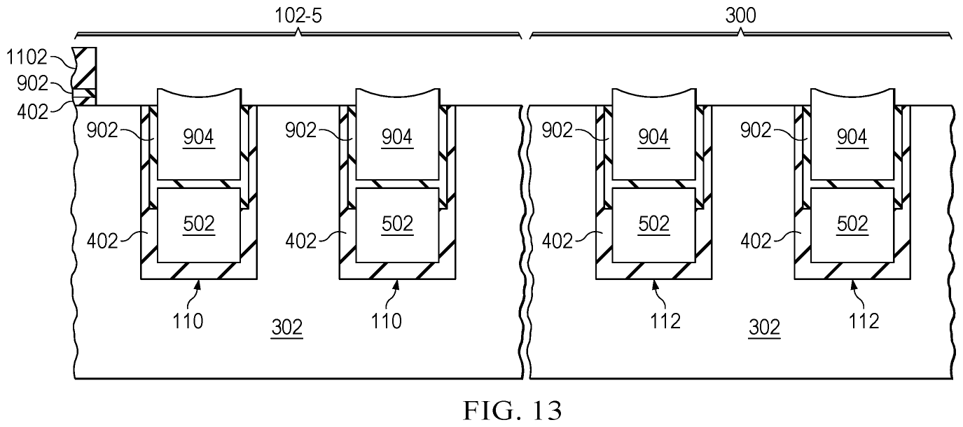

Referring to FIG. 13, with the patterned photoresist over the dielectric layer 1102, exposed portions of the dielectric layer 1102, second conformal dielectric layer 902, and first conformal dielectric layer 402 are etched. Portions of the top surface of the semiconductor substrate 302 not directly underlying the patterned photoresist 1202 may be exposed as a result of the etch. Remaining portions of the dielectric layer 1102, second conformal dielectric layer 902, and first conformal dielectric layer 402 over the top surface of the semiconductor substrate 302 can form an isolation structure over the top surface of the semiconductor substrate 302 in the IC die area 102-5. The isolation structure can isolate a subsequently formed gate structure (e.g., gate electrode) from another structure disposed in the semiconductor substrate 302. Portions of the conformal dielectric layers 402, 902 remain in the first recesses 110 and second recesses 112. The dielectric layer 1102, second conformal dielectric layer 902, and first conformal dielectric layer 402 can be etched using an appropriate etch process, such as ME. After the etch, the patterned photoresist 1202 is removed, such as by an ash process.

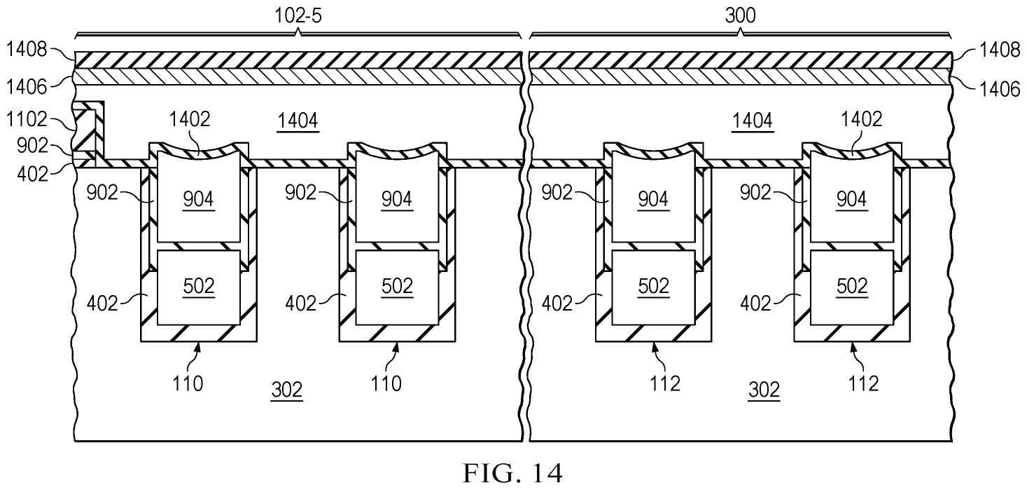

Referring to FIG. 14, layers that are to form gate structures are formed over the semiconductor substrate 302. A gate dielectric layer 1402 is formed over the semiconductor substrate 302. A conductive semiconductor layer 1404 is formed over the gate dielectric layer 1402. A metal layer 1406 is formed over the conductive semiconductor layer 1404. A dielectric layer 1408 is formed over the metal layer 1406. The gate dielectric layer 1402, in some examples, can be an oxide formed by oxidation or deposited by CVD or the like. The conductive semiconductor layer 1404 can be doped polysilicon, and can be deposited by CVD, PVD, or the like. The metal layer 1406 can be tungsten, copper, titanium, or the like, and can be deposited by CVD, PVD, or the like. The dielectric layer 1408 can be an oxide, such as TEOS, or the like, and can be deposited by CVD or the like.

Referring to FIG. 15, a patterned photoresist 1502 is formed over the dielectric layer 1408 in the IC die area 102-5. The patterned photoresist 1502 can be formed using a photolithography process as described above. The second recesses 112 (with conformal dielectric layers 402, 902 and fill material 502, 904 disposed therein) are used as an alignment mark for aligning a photomask in the photolithography process.

Referring to FIG. 16, with the patterned photoresist over the dielectric layer 1408, exposed portions of the dielectric layer 1408, metal layer 1406, conductive semiconductor layer 1404, and gate dielectric layer 1402 are etched. Portions of the top surface of the semiconductor substrate 302 not directly underlying the patterned photoresist 1502 may be exposed as a result of the etch. Remaining portions of the dielectric layer 1408, metal layer 1406, conductive semiconductor layer 1404, and gate dielectric layer 1402 over the top surface of the semiconductor substrate 302 can form gate structures in the IC die area 102-5 (e.g., for transistors). The dielectric layer 1408, metal layer 1406, conductive semiconductor layer 1404, and gate dielectric layer 1402 can be etched using an appropriate etch process, such as RIE. The layers and materials for the gate structures can differ in other examples. After the etch, the patterned photoresist 1502 is removed, such as by an ash process.

As a result of the foregoing processing, the first recesses 110, with the conformal dielectric layers 402, 902 and fill material 502, 904 therein, form isolation structures (e.g., DTI structures) in the IC die area 102-5. The second recesses 112 can generally undergo the processing that the first recesses 110 undergo and can be used as an alignment mark for aligning photomasks in photolithography processes as described above.

Referring to the second example of FIGS. 17 through 30, the same processing stages as described with respect to first example of FIGS. 3 through 16 are implemented. Accordingly, some repetitive description is omitted below for brevity.

In the context of the second example of FIGS. 17 through 30, referring to block 202 of FIG. 2, a first recess in an IC die area and a second recess in an alignment mark area are formed in a semiconductor substrate. In FIG. 17, first recesses 110 are formed in an IC die area 102-5 in a semiconductor substrate 302, and second recesses 112 are formed in an alignment mark area 300 in the semiconductor substrate 302. The first recesses 110 in the IC die area 102-5 each have a width 1720, and the second recesses 112 in the alignment mark area 300 each have a width 1722. The width 1720 of the first recesses 110 in the IC die area 102-5 is less than the width 1722 of the second recesses 112 in the alignment mark area 300.

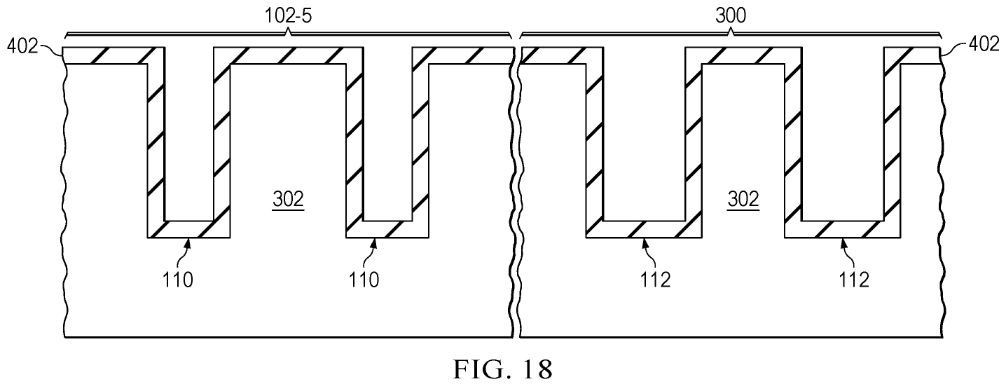

Referring to block 204 of FIG. 2, a conformal dielectric layer is formed in the first recess and the second recess and over the semiconductor substrate. In FIG. 18, a first conformal dielectric layer 402 is formed in the first recesses 110 in the IC die area 102-5 and the second recesses 112 in the alignment mark area 300 and over the semiconductor substrate 302.

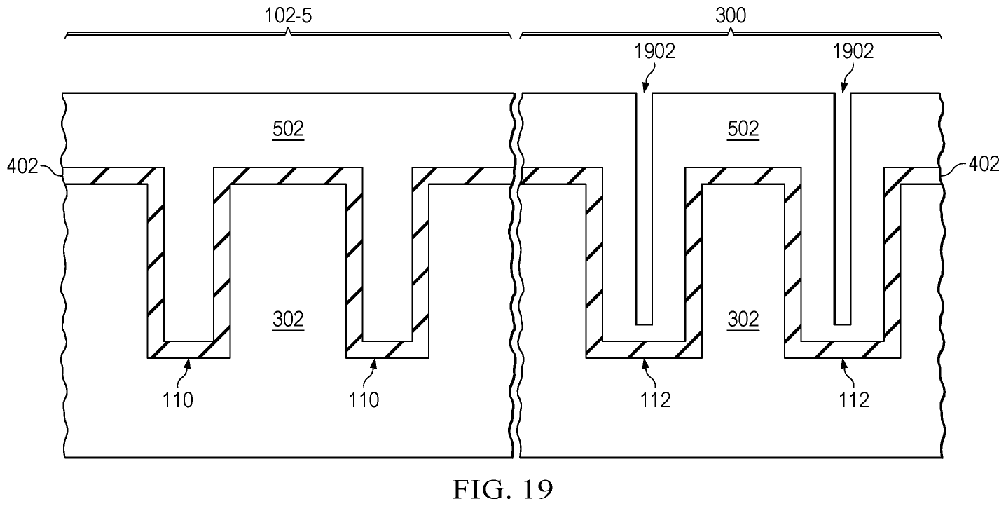

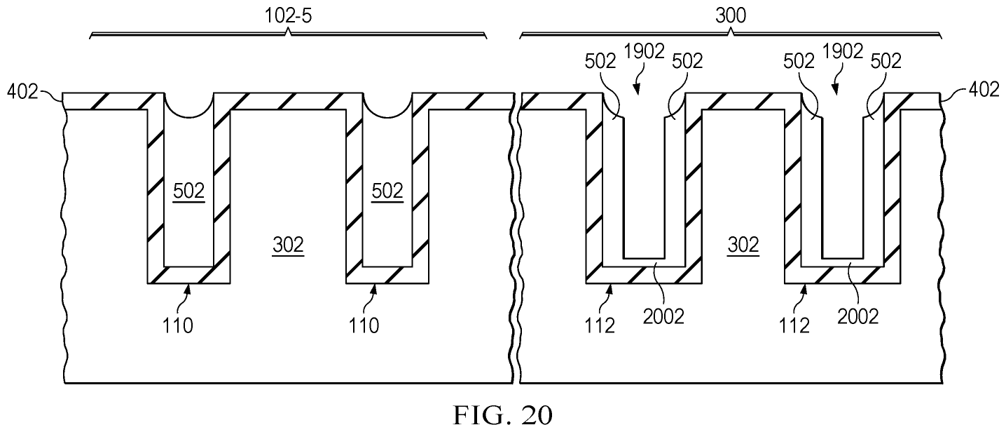

Referring to block 206 of FIG. 2, a fill material is formed over the conformal dielectric layer. In FIG. 19, a first fill material 502 is formed over the first conformal dielectric layer 402. The first fill material 502, as deposited, fills the previously un-filled portions of the first recesses 110 over the first conformal dielectric layer 402 and is deposited to a thickness over the top surface of the semiconductor substrate 302. Due, at least in part, to the width 1722 of the second recesses 112 being greater than the width 1720 of the first recesses 110, the first fill material 502, as illustrated, does not fill the second recesses 112. The first fill material 502 is deposited on the first conformal dielectric layer 402 along the sidewalls of the second recesses 112, and a seam 1902 or void is between portions of the first fill material 502 along opposing sidewalls of a respective second recess 112. The seam 1902 (or void) may be where the opposing portions of the first fill material 502 do not coalesce because the thickness of the first fill material 502 is insufficient for coalescence. For example, if the thickness of the first fill material 502 along a sidewall of the second recess 112 is less than half of the width 1722 of the second recess 112, the first fill material 502 may not coalesce in the second recess 112. The first fill material 502 is also deposited on the first conformal dielectric layer 402 on bottom surface of the Referring to block 208 of FIG. 2, the fill material is recessed in the first recess and the second recess. In FIG. 20, the first fill material 502 is recessed in the first recesses 110 in the IC die area 102-5 and in the second recesses 112 in the alignment mark area 300. The first fill material 502 in the first recesses 110 and the second recesses 112 is recessed below a top surface of the first conformal dielectric layer 402, which may be over a top surface of the semiconductor substrate 302. The first fill material 502 is removed from over the top surface of the first conformal dielectric layer 402, and respective remaining first fill material 502 in the first recesses 110 and second recesses 112 may have a dished upper surface. The first fill material 502 in the second recesses 112 may be laterally etched from the seam 1902. Additionally, a residual portion 2002 of the first fill material 502 may remain on the first conformal dielectric layer 402 on the bottom surface of the respective second recess 112 laterally between the portions of the first fill material 502 along the sidewalls of the second recess 112.

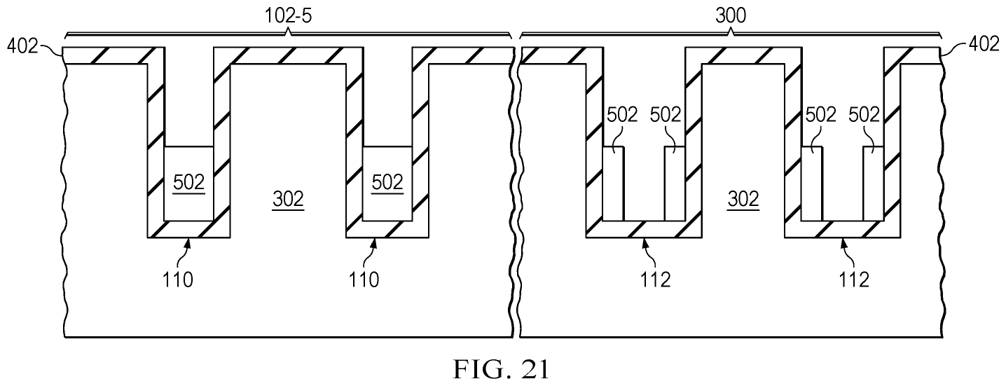

Referring to block 210 of FIG. 2, a patterned photoresist is formed over the semiconductor substrate, and at block 212, the fill material in the first recess and the second recess is etched. In FIG. 21, the first fill material 502 in the first recesses 110 in the IC die area 102-5 is etched, and the first fill material 502 in the second recesses 112 in the alignment mark area 300 is etched. The patterned photoresist (which is formed over the semiconductor substrate 302) of block 210 is not illustrated in FIG. 21 since the patterned photoresist is not disposed in the area of the cross-section of FIG. 21 but is disposed in, for example, another area of the IC die area 102-5. The first recesses 110 and second recesses 112 (with first conformal dielectric layer 402 and first fill material 502 disposed therein) are exposed through the patterned photoresist formed at block 210. No portion of the patterned photoresist is disposed directly over the first recesses 110, and no portion of the patterned photoresist is disposed directly over the second recesses 112. The patterned photoresist can be formed using a photolithography process as described above. The patterned photoresist can be formed using a photolithography process as described above. The second recesses 112 (with first conformal dielectric layer 402 and first fill material 502 disposed therein) may be used as an alignment mark for aligning a photomask in the photolithography process. With the patterned photoresist over the semiconductor substrate 302, the first fill material 502 in the first recesses 110 and second recesses 112 is etched. The etch removes any residual portion 2002 of the first fill material 502 along the bottom surface in the Referring to block 214 of FIG. 2, the patterned photoresist is removed. After the first fill material 502 in the first recesses 110 and second recesses 112 is etched, the patterned photoresist (formed at block 210) can be removed using an ash process. The semiconductor substrate 302 can thereafter be cleaned using a wet strip or clean process.

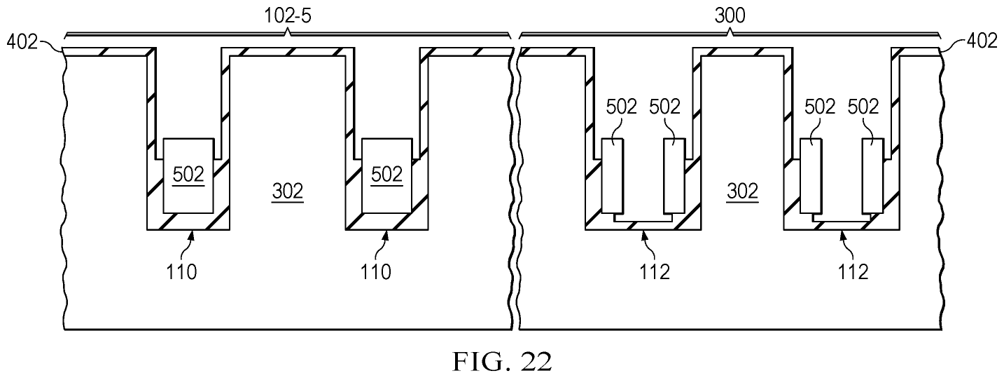

Referring to block 216 of FIG. 2, the conformal dielectric layer is etched. In FIG. 22, the first conformal dielectric layer 402 is etched. The etch can thin exposed portions of the first conformal dielectric layer 402, including along the bottom surfaces of the second recesses 112.

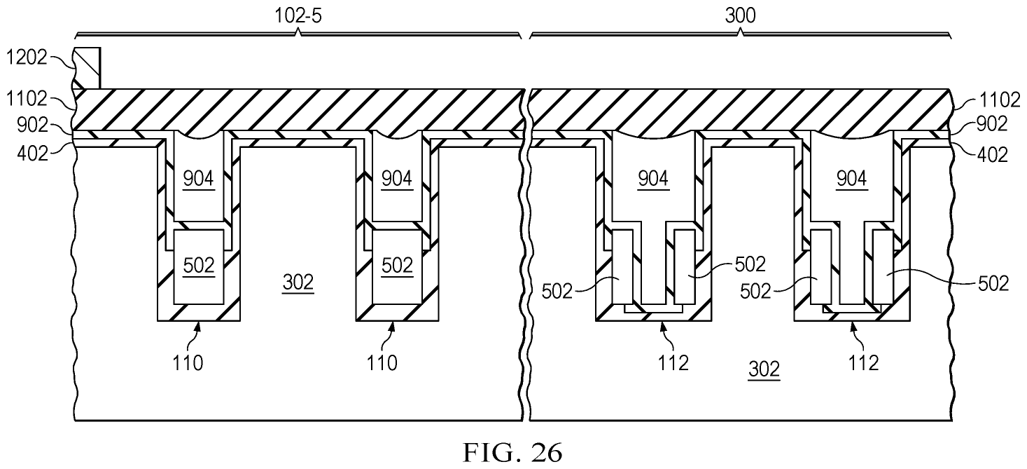

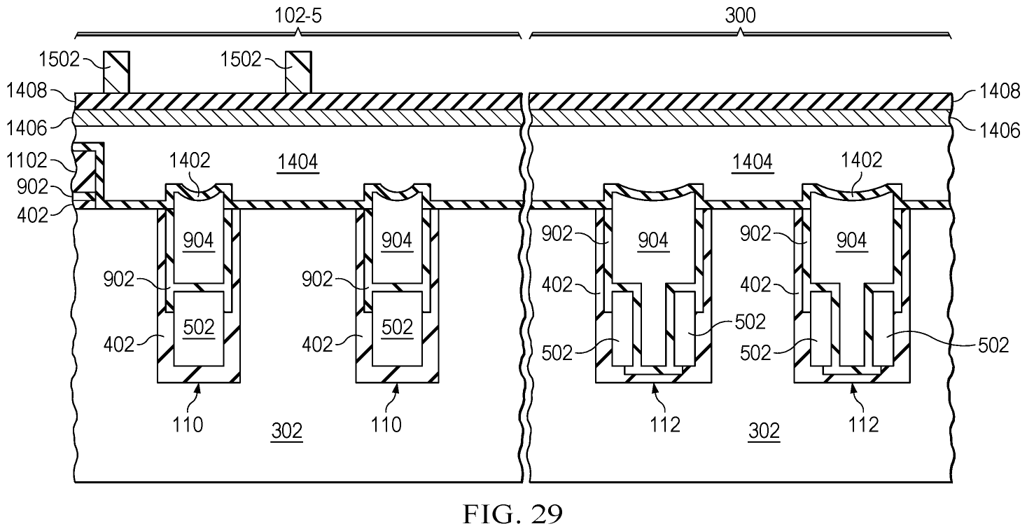

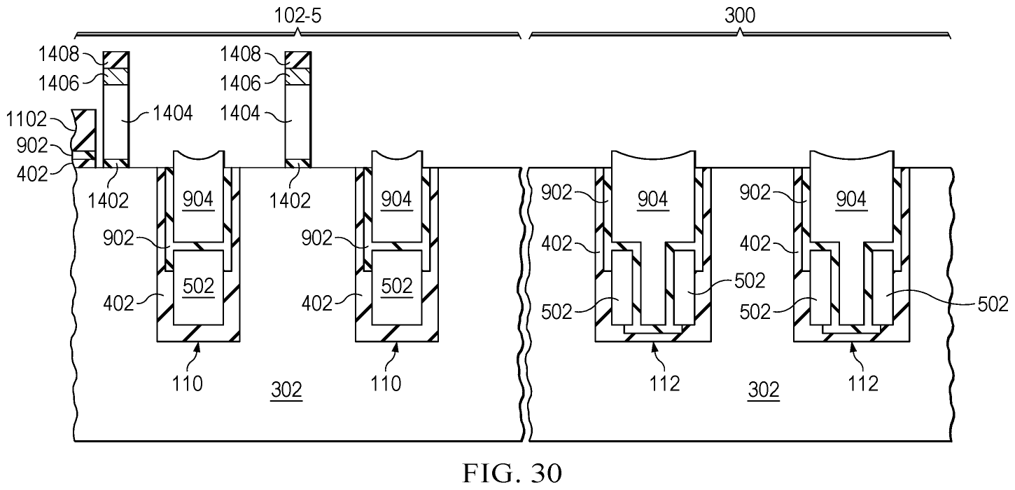

Referring to block 218 of FIG. 2, additional processing is, optionally, performed on the semiconductor substrate, and at block 220, the second recess (and any material disposed therein) is used as an alignment mark to align a photomask. Patterning photoresists in FIGS. 26 and 29 are examples in which the second recesses 112 (and material disposed therein) in the alignment mark area 300 are used as an alignment mark to align a photomask. Other figures through FIG. 30 illustrate various additional processing that may be performed.

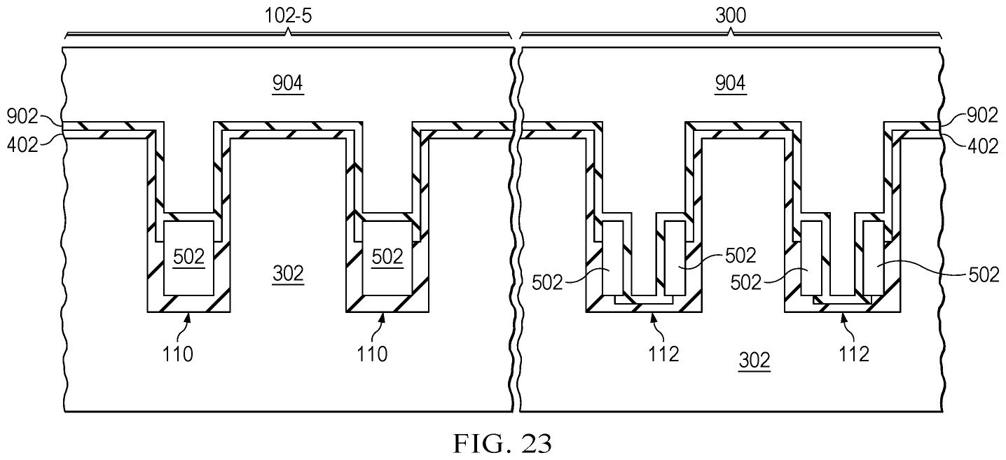

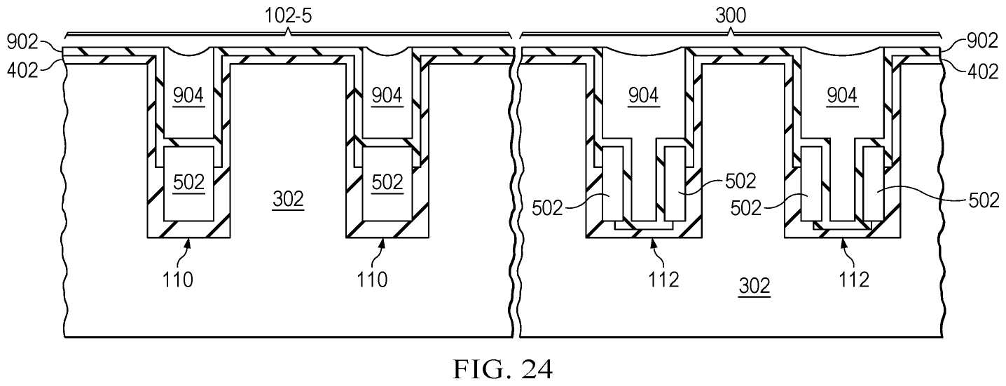

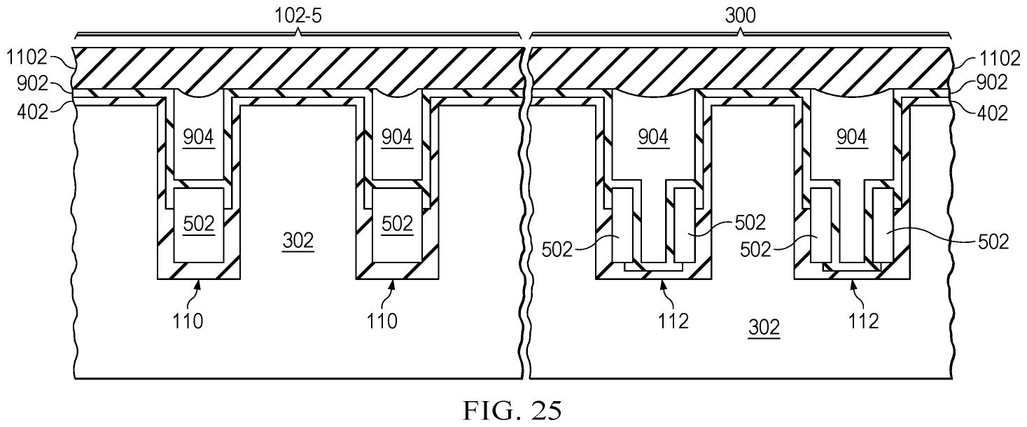

Referring to FIG. 23, a second conformal dielectric layer 902 is formed over the first conformal dielectric layer 402 and first fill material 502, and second fill material 904 is formed over the second conformal dielectric layer 902. In the second recesses 112, the second conformal dielectric layer 902 is formed along opposing sidewalls of the first fill material 502 disposed along sidewalls of the respective second recess 112. The second conformal dielectric layer 902 is also formed over the first conformal dielectric layer 402 on a bottom surface of the respective second recess 112 between the first fill material 502 in the respective second recess 112. The second fill material 904, as deposited, fills the previously un-filled portions of the first recesses 110 and second recesses 112 over the second conformal dielectric layer 902 and is deposited to a thickness over the top surface of the semiconductor substrate 302. Referring to FIG. 24, the second fill material 904 is recessed in the first recesses 110 in the IC die area 102-5 and in the second recesses 112 in the alignment mark area 300. Referring to FIG. 25, a dielectric layer 1102 is deposited over the second conformal dielectric layer 902 and the second fill material 904.

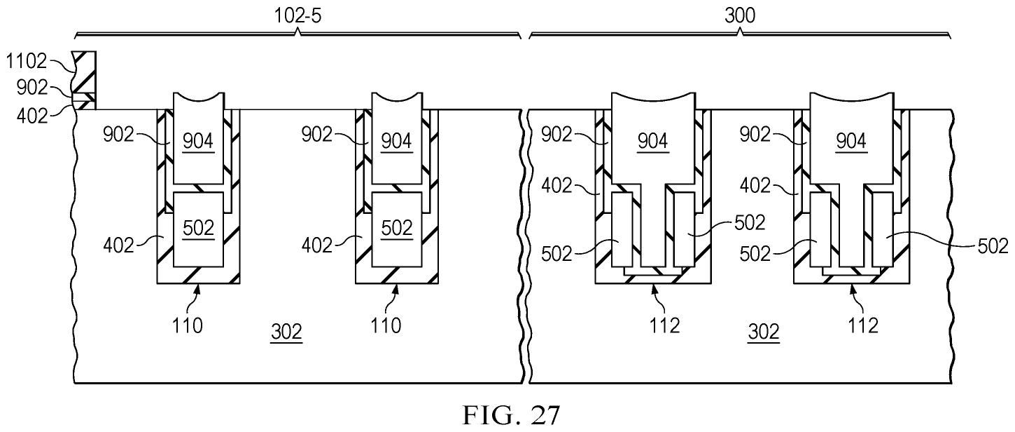

Referring to FIG. 26, a patterned photoresist 1202 is formed over the dielectric layer 1102 in the IC die area 102-5. The patterned photoresist 1202 can be formed using a photolithography process as described above. The second recesses 112 (with conformal dielectric layers 402, 902 and fill material 502, 904 disposed therein) are used as an alignment mark for aligning a photomask in the photolithography process. Referring to FIG. 27, with the patterned photoresist over the dielectric layer 1102, exposed portions of the dielectric layer 1102, second conformal dielectric layer 902, and first conformal dielectric layer 402 are etched. After the etch, the patterned photoresist 1202 is removed, such as by an ash process.

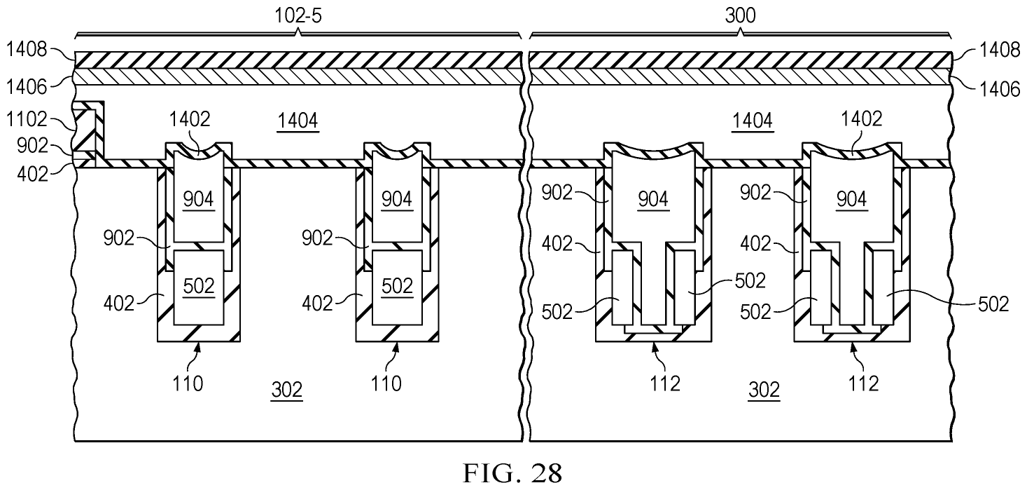

Referring to FIG. 28 layers that are to form gate structures are formed over the semiconductor substrate 302. A gate dielectric layer 1402 is formed over the semiconductor substrate 302. A conductive semiconductor layer 1404 is formed over the gate dielectric layer 1402. A metal layer 1406 is formed over the conductive semiconductor layer 1404. A dielectric layer 1408 is formed over the metal layer 1406. Referring to FIG. 29, a patterned photoresist 1502 is formed over the dielectric layer 1408 in the IC die area 102-5. The patterned photoresist 1502 can be formed using a photolithography process as described above. The second recesses 112 (with conformal dielectric layers 402, 902 and fill material 502, 904 disposed therein) are used as an alignment mark for aligning a photomask in the photolithography process. Referring to FIG. 30, with the patterned photoresist over the dielectric layer 1408, exposed portions of the dielectric layer 1408, metal layer 1406, conductive semiconductor layer 1404, and gate dielectric layer 1402 are etched. After the etch, the patterned photoresist 1502 is removed, such as by an ash process.

As a result of the foregoing processing, the first recesses 110, with the conformal dielectric layers 402, 902 and fill material 502, 904 therein, form isolation structures (e.g., DTI structures) in the IC die area 102-5. The second recesses 112 can generally undergo the processing that the first recesses 110 undergo and can be used as an alignment mark for aligning photomasks in photolithography processes as described above.

It has been discovered that when a residual portion of fill material (like residual portion 2002) remains at the bottom of a recess after etching an underlying conformal dielectric layer (like the first conformal dielectric layer 402), the residual portion may break from inside the recess and become lodged in a die area during a wet cleaning following the etch of the conformal dielectric layer. The residual portion in the IC die area can result in defects in devices and circuits formed in the IC die area.

In the foregoing examples, the residual portion can be removed or avoided. For example, in the first example of FIGS. 3 through 16, the widths 320, 322 are equal such that the second recesses 112 are filled with the first fill material 502 in FIG. 5 like the first recesses 110. The second recesses 112 being filled with the first fill material 502 can avoid respective seams or voids being formed in the second recesses 112. Without a seam or void, typically, no residual portion is formed in the second recesses 112. In the second example of FIGS. 17 through 30, although seams 1902 are formed resulting in residual portions 2002 as shown in FIG. 20, the residual portions 2002 are removed by etching the residual portions 2002 in FIG. 21. Hence, the residual portions 2002 are generally not present during a cleaning process following the etching of the first conformal dielectric layer 402 in FIG. 22. By removing or avoiding such residual portions, occurrence of defects in an IC die area (e.g., IC die area 102-5) resulting from residual portions becoming lodged therein may be reduced.

Although various examples have been described in detail, it should be understood that various changes, substitutions, and alterations can be made therein without departing from the scope defined by the appended claims.

What is claimed is:

1. A method of semiconductor processing, the method comprising:
forming a first recess and a second recess in a semiconductor substrate;
forming a first conformal dielectric layer in the first recess and the second recess and over the semiconductor substrate;
forming a first fill material over the first conformal dielectric layer in the first recess and over the first conformal dielectric layer in the second recess, the first fill material filling at least the first recess over the first conformal dielectric layer;
recessing the first fill material in the first recess and the first fill material in the second recess to below a top surface of the first conformal dielectric layer;
etching the recessed first fill material in the first recess and the recessed first fill material in the second recess; and
etching exposed portions of the first conformal dielectric layer, wherein the second recess including the first conformal dielectric layer and the recessed first fill material disposed therein forms an alignment mark.

2. The method of claim 1, wherein a width of the first recess is equal to a width of the second recess.

3. The method of claim 1, wherein a width of the first recess is less than a width of the second recess.

4. The method of claim 1, wherein forming the first fill material over the first conformal dielectric layer in the second recess fills the second recess over the first conformal dielectric layer with the first fill material.

5. The method of claim 1, wherein after forming the first fill material over the first conformal dielectric layer in the second recess, the first fill material over the first conformal dielectric layer in the second recess has a seam in the second recess.

6. The method of claim 1, wherein during etching the recessed first fill material, a patterned photoresist is disposed over the semiconductor substrate, no portion of the patterned photoresist being disposed directly over the first recess during etching the recessed first fill material, no portion of the patterned photoresist being disposed directly over the second recess during etching the recessed first fill material.

7. The method of claim 1 further comprising aligning a photomask relative to the semiconductor substrate using the second recess as an alignment mark, wherein the second recess includes the first conformal dielectric layer and the recessed first fill material disposed therein.

8. The method of claim 1 further comprising:
forming a second conformal dielectric layer over the recessed first fill material and the first conformal dielectric layer in the first recess and over the recessed first fill material and the first conformal dielectric layer in the second recess; and
forming a second fill material over the second conformal dielectric layer in the first recess and over the second conformal dielectric layer in the second recess, the second fill material filling the first recess over the second conformal dielectric layer, the second fill material filling the second recess over the second conformal dielectric layer, wherein the first conformal dielectric layer, the recessed first fill material, the second conformal dielectric layer, and the second fill material in the first recess form an isolation structure in the semiconductor substrate.

9. A method of semiconductor processing, the method comprising:
forming a first trench and a second trench in a semiconductor substrate, the first trench being in a die area on the semiconductor substrate, the second trench being in a scribe line area on the semiconductor substrate;
forming a first conformal dielectric layer in the first trench and the second trench and over the semiconductor substrate;
forming a first semiconductor material over the first conformal dielectric layer in the first trench and over the first conformal dielectric layer in the second trench;
recessing the first semiconductor material in the first trench and the first semiconductor material in the second trench to below a top surface of the first conformal dielectric layer;
etching the recessed first semiconductor material in the first trench and the recessed first semiconductor material in the second trench; and
etching exposed portions of the first conformal dielectric layer.

10. The method of claim 9, wherein:
the first trench has a first longitudinal length and a first width perpendicular to the first longitudinal length;
the second trench has a second longitudinal length and a second width perpendicular to the second longitudinal length; and
the first width is equal to the second width.

11. The method of claim 9, wherein:
the first trench has a first longitudinal length and a first width perpendicular to the first longitudinal length;
the second trench has a second longitudinal length and a second width perpendicular to the second longitudinal length; and
the first width is less than the second width.

12. The method of claim 9, wherein during etching the recessed first semiconductor material, a photoresist is disposed over the semiconductor substrate, no portion of the photoresist being disposed directly over the first trench during etching the recessed first semiconductor material, no portion of the photoresist being disposed directly over the second trench during etching the recessed first semiconductor material.

13. The method of claim 9 further comprising aligning a photomask relative to the semiconductor substrate using the second trench as an alignment mark, wherein the second trench includes the first conformal dielectric layer and the recessed first semiconductor material disposed therein.

14. The method of claim 9 further comprising:
forming a second conformal dielectric layer over the recessed first semiconductor material and the first conformal dielectric layer in the first trench and over the recessed first semiconductor material and the first conformal dielectric layer in the second trench; and
forming a second semiconductor material over the second conformal dielectric layer in the first trench and over the second conformal dielectric layer in the second trench, the second semiconductor material filling the first trench over the second conformal dielectric layer, the second semiconductor material filling the second trench over the second conformal dielectric layer, wherein the first conformal dielectric layer, the recessed first semiconductor material, the second conformal dielectric layer, and the second semiconductor material in the first trench form a trench isolation structure in the die area.

15. A method of semiconductor processing, the method comprising:
forming an isolation trench and an alignment mark trench in a semiconductor substrate, the isolation trench being in a die area on the semiconductor substrate;
forming a first conformal dielectric layer in the isolation trench and the alignment mark trench and over the semiconductor substrate;
forming a first fill material over the first conformal dielectric layer in the isolation trench and over the first conformal dielectric layer in the alignment mark trench;
recessing the first fill material in the isolation trench and the first fill material in the alignment mark trench to below a top surface of the first conformal dielectric layer;
etching the recessed first fill material in the isolation trench and the recessed first fill material in the alignment mark trench;
etching exposed portions of the first conformal dielectric layer;
forming a second conformal dielectric layer over the recessed first fill material and the first conformal dielectric layer in the isolation trench and over the recessed first fill material and the first conformal dielectric layer in the alignment mark trench;
forming a second fill material over the second conformal dielectric layer in the isolation trench and over the second conformal dielectric layer in the alignment mark trench, the second fill material filling the isolation trench over the second conformal dielectric layer, the second fill material filling the alignment mark trench over the second conformal dielectric layer, wherein the first conformal dielectric layer, the recessed first fill material, the second conformal dielectric layer, and the second fill material in the isolation trench form a trench isolation structure in the die area; and
aligning a photomask relative to the semiconductor substrate using the alignment mark trench as an alignment mark, wherein the alignment mark trench includes the first conformal dielectric layer, the recessed first fill material, the second conformal dielectric layer, and the second fill material disposed therein.

16. The method of claim 15, wherein:
the isolation trench has a first longitudinal length and a first width perpendicular to the first longitudinal length;
the alignment mark trench has a second longitudinal length and a second width perpendicular to the second longitudinal length; and
the first width is equal to the second width.

17. The method of claim 15, wherein:
the isolation trench has a first longitudinal length and a first width perpendicular to the first longitudinal length;
the alignment mark trench has a second longitudinal length and a second width perpendicular to the second longitudinal length; and
the first width is less than the second width.

18. The method of claim 15, wherein during etching the recessed first fill material, a photoresist is disposed over the semiconductor substrate, no portion of the photoresist being disposed directly over the isolation trench during etching the recessed first fill material, no portion of the photoresist being disposed directly over the alignment mark trench during etching the recessed first fill material.

19. The method of claim 15 further comprising:
patterning a photoresist disposed over the semiconductor substrate using the aligned photomask; and
etching a dielectric layer disposed over the semiconductor substrate using the patterned photoresist as a mask.

20. The method of claim 15 further comprising:
patterning a photoresist disposed over the semiconductor substrate using the aligned photomask; and
etching a conductive layer disposed over the semiconductor substrate using the patterned photoresist as a mask, the etched conductive layer forming at least a portion of a gate structure disposed in the die area and over the semiconductor substrate.
